(19) United States
(12) Patent Application Publication
(10) Pub. No.: US 2025/0284200 A1
(43) Pub. Date: Sep. 11, 2025

(54) DIFFUSER-LESS GRAY-TONE LITHOGRAPHY PROCESS, MASK DESIGN, AND FABRICATION METHOD

(71) Applicant: Applied Materials, Inc., Santa Clara, CA (US)

(72) Inventors: Wenhui WANG, San Jose, CA (US); Yongan XU, Santa Clara, CA (US); Alex Han YOUNG, Redwood City, CA (US); Ludovic GODET, Sunnyvale, CA (US); Chia-Wei HUANG, Sunnyvale, CA (US); Yingdong LUO, Newark, CA (US); Chan Juan XING, San Jose, CA (US); Zefang WANG, Santa Clara, CA (US); Lei JIANG, San Ramon, CA (US)

(21) Appl. No.: 19/057,024

(22) Filed: Feb. 19, 2025

Related U.S. Application Data
(60) Provisional application No. 63/563,715, filed on Mar. 11, 2024.

(51) Int. Cl. G03F 7/00; G03F 1/54; G03F 1/76

(52) U.S. Cl. CPC G03F 7/70283; G03F 1/54; G03F 1/76; G03F 7/70625

(57) ABSTRACT

The present disclosure generally relates to mask designs and fabrication for gray-tone lithography. More specifically, embodiments described herein relate to masks designed with a specific pitch to avoid the need for a diffuser. In some embodiments, a mask is provided. The mask includes a substrate and a gray-tone pattern grating disposed on the substrate. The gray-tone pattern grating is defined by a plurality of structures disposed on the substrate. The structures include an absorber layer disposed on the substrate. The gray-tone pattern grating has a pitch of less than or equal to an exposure wavelength of light to pass through the structures. The pitch is defined as a distance between a centers of adjacent structures of the plurality of structures.

### CROSS-REFERENCE TO RELATED APPLICATIONS

This Application claims the benefit of U.S. Provisional Application 63/563,715 filed on Mar. 11, 2024, and entitled “Diffuser-Less Gray-Tone Lithography Process, Mask Design, and Fabrication Method,” wherein the entire contents of which are incorporated by reference.

### BACKGROUND

### Field

Embodiments of the present disclosure generally relate to mask designs and fabrication for gray-tone lithography. More specifically, embodiments described herein relate to masks designed with a specific pitch to avoid needing diffusers.

### Description of the Related Art

Virtual reality (VR) is generally considered to be a computer-generated simulated environment in which a user has an apparent physical presence. A virtual reality experience can be generated in 3D and viewed with a head-mounted display (HMD), such as glasses or other wearable display devices that have near-eye display panels as lenses to display a virtual reality environment that replaces an actual environment. Augmented reality (AR), enables an experience in which a user can still see through the display lenses of the glasses or other HMD device to view the surrounding environment, yet also see images of virtual objects that are generated to appear as part of the environment. AR can include any type of input, such as audio and haptic inputs, as well as virtual images, graphics, and video that enhance or augment the environment that the user experiences.

### SUMMARY

In one embodiment, which may be combined with other embodiments, a mask for gray-tone lithography is provided. The mask includes a substrate and a gray-tone pattern grating disposed on the substrate. The gray-tone pattern grating is defined by a plurality of structures disposed on the substrate. The structures include an absorber layer disposed on the substrate. The gray-tone pattern grating has a pitch that is less than or equal to an exposure wavelength of light to pass through the structures. The pitch is defined as a distance between a centers of adjacent structures of the plurality of structures.

In another embodiment, which may be combined with other embodiments, a mask assembly for gray-tone lithography includes a mask, a mask holder, a UV light source, and a substrate support. The mask includes a substrate, and a gray-tone pattern grating with a plurality of grating structures formed from an absorber layer disposed on the substrate. The mask holder is operable to secure the mask, and the mask is inserted in the mask holder. The UV light source is disposed above the mask and is operable to project UV light through the mask. The gray-tone pattern grating has a pitch that is less than or equal to a wavelength of UV light projected by the UV light source. The pitch is defined as a distance between centers of adjacent grating structures of the plurality of grating structures. The substrate support is positioned below the mask.

In another embodiment, which may be combined with other embodiments, a method of fabricating a mask is provided. The method includes depositing an absorber layer on a first surface of a substrate. The method further includes forming a plurality of structures in the absorber layer by removing sections of the absorber layer. The structures form a grating having a pitch that is less than or equal to an exposure wavelength of light to pass through the structures. The pitch is defined as a distance between centers of adjacent grating structures of the plurality of structures.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of the scope of the disclosure, as the disclosure may admit to other equally effective embodiments.

FIG. 1 is a cross-sectional view of a mask assembly, according to some embodiments.

FIGS. 2A and 2B are cross-sectional views of a mask in different orientations, according to some embodiments.

FIG. 3 is a flow diagram of a method of forming a mask, according to some embodiments.

FIGS. 4A, 4B, 4C, and 4D, are schematic, cross-sectional views of a substrate during a method of forming a mask, according to some embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure generally relates to mask designs and fabrication for gray-tone lithography. More specifically, embodiments described herein relate to masks designed with a specific pitch to avoid needing diffusers.

AR and VR devices may be partially formed though gray-tone lithography using masks. A gray-tone mask modulates the intensity of light that is passed through to adjust the dose exposed on a resist layer. Gray-tone masks for gray-tone lithography may be made using an E-beam writer or laser writer.

One way to modulate light intensity is by varying the pattern density of opening areas of the mask versus opaque areas of the mask. Current gray-tone masks, due to the limitation of mask writer tool and cost, have patterns that have a critical dimension and a pitch that is larger than the wavelength of light used for the gray-tone lithography. Specifically, current gray-tone masks have a binary design with a pitch ranging from a few micrometers to several tens micrometers. Therefore, the mask pattern may be potentially resolved on a wafer, which one may desire to avoid. Separate diffusers can be used to scatter the incident light before entering the mask to perform a photolithography process. Scattering the light causes the mask pattern to not be resolved on wafer; however, the diffuser causes transmission loss of light causing throughput delays. The diffuser also causes large transition zones between different thickness targets, which can be a significant issue in small designs. A mask with a diffuser is also complicated to perform optical proximity correction (OPC) to correct errors in the photolithography process. Therefore, what is needed in the art is mask designs that may not require a diffuser.

Accordingly, as described herein, a transparent wafer (such as a 30 millimeter (mm) wafer) can be used to form a gray-tone lithography mask that does not require a diffuser to operate. In some embodiments, which may be combined with other embodiments, the wafer mask has a sub-resolution pattern to have a pitch less than the wavelength of light. As a result, the wafer mask scatters light, and makes a diffuser unnecessary. The wafer mask can be attached to a mask holder and used as a standard mask. In some embodiments, which may be combined with other embodiments, the wafer mask has the benefits of a maximum mask size fit up to 300 mm, better pattern density control, lower cost, and design freedom. The wafer mask is easy to clean and perform metrology using standard clean and metrology tools. The wafer mask also allows for OPC to be performed.

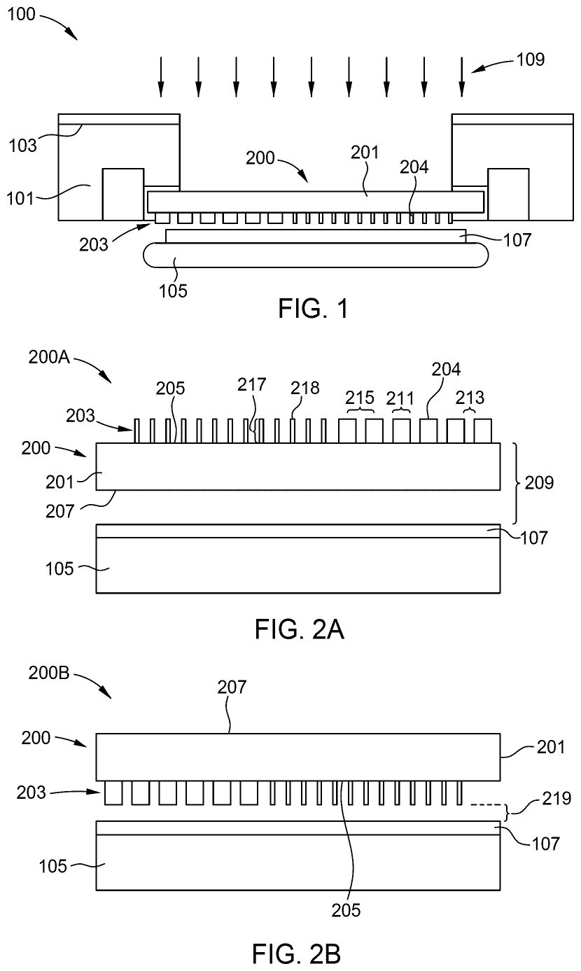

FIG. 1 is a cross-sectional view of a mask assembly 100 according to some embodiments. The mask assembly 100 includes a mask 200, a mask holder 101, and an opaque layer 103. The mask assembly 100 is positioned over a wafer 105 having a resist layer 107 disposed thereon. The mask assembly 100 is operable to secure the mask 200 in position. In some embodiments, which may be combined with other embodiments, the mask holder 101 has a similar shape to traditional photo masks used in photolithography processes. The wafer 105 is disposed on a substrate support (not shown). The substrate support may be aligned below the mask 200 and may be operable to hold the wafer 105 under the mask assembly 100 and mask 200. Ultraviolet (UV) light 109 is projected above the mask assembly 100 through the mask 200. For instance, a UV light source (not shown) may be disposed above the mask 200 that is configured to generate the UV light 109 such that the UV light 109 is projected through the mask 200. The mask 200 partially blocks portions on the UV light 109 so that the UV light 109 patterns the resist layer 107 through photolithography. The more UV light 109 that interacts with a portion of the resist layer 107 the more of the resist layer 107 is removed in the photolithography process.

The mask 200 includes a mask substrate 201 and a mask grating 203. The mask substrate 201 includes at least one of fused silica, soda-lime glass, or other similar materials. In some embodiments, which may be combined with other embodiments, the mask substrate 201 may have a thickness that is in a range of about 700 micrometers (μm) to about 850 μm, such as about 750 μm to about 800 μm, or such as about 775 μm. The mask grating 203 is disposed on the mask substrate 201. The mask grating 203 includes grating structures 204. The grating structures 204 define a gray-tone pattern.

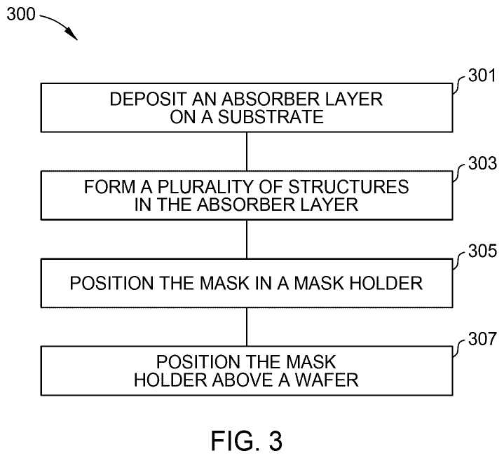

FIGS. 2A-2B are cross-sectional views of the mask 200 in different orientations according to some embodiments. FIG. 2A shows the mask 200 in a first orientation 200A that illustrates the mask grating 203 disposed on a first surface 205 of the mask substrate 201. A second surface 207 of the mask substrate 201 opposes the first surface 205 and faces the wafer 105. In FIG. 2A, the mask grating 203 is shown spaced at a first distance 209 away from the resist layer 107 of the wafer 105. In some embodiments, which may be combined with other embodiments, the first distance 209 may range from a thickness of the mask 200 to about 8 mm, such as about 800 microns to about 6000 μm, or such as 1000 μm. The first distance 209 includes the thickness of the mask substrate 201 and the distance from second surface 207 of the mask substrate 201 to the resist layer 107. An edge transition zone is caused by the mask assembly 100 having an opening diameter equal to or smaller than a diameter of the wafer 105 and the distance from the mask 200 to the resist layer 107. Scattering of UV light 109 at the top surface of mask holder 101 will cause unwanted light exposed beyond the edge of the wafer 105 (FIG. 1). An exclusion zone in design or optical proximity correction is needed to achieve thickness on target. The opaque layer 103 may be deposited on the top surface of the mask holder 101 to simplify the optical scattering scenario. The width of the edge transition zone depends on the property of the illuminated UV light 109 and the distance between the opaque layer 103 and the surface of the resist layer 107. Since the edge transition zone may only affect areas close to the edge of the wafer 105, when the edge transition zone is controlled to be within the Edge-Bead-Removal (EBR) region, the edge transition zone will not affect the active device area. An edge transition zone of less than 200 microns is achievable.

The grating structures 204 may be defined by a critical dimension 211, a space width 213, a pitch 215, and a thickness 217. The critical dimension 211 is defined as the width of the grating structures 204. The space width 213 is defined as the distance between adjacent grating structures 204. The pitch 215 is defined by a distance between the center of a single grating structure 204 and the center of an adjacent grating structure 204. The thickness 217 is defined as the distance from the first surface 205 to a top surface 218 of the grating structures 204. The thickness 217 may be dependent on the material used in the grating structures and generally is in a range from about 30 nanometers (nm) to about 150 nm, such as about 60 nm to about 120 nm, or such as about 80 nm to about 100 nm. In some embodiments, which may be combined with other embodiments, adjusting the amount of UV light 109 passing through the mask 200 is performed by adjusting the critical dimension 211 while keeping the pitch 215 constant or adjusting the pitch 215 while keeping the critical dimension 211 constant. In some embodiments, which may be combined with other embodiments, both the critical dimension 211 and the pitch 215 are adjusted to control the amount of UV light 109 passing through the mask 200. The grating structures 204 may be oriented in a line and space pattern or a two-dimensional pattern, such as a contact holes and pillar pattern.

The pitch 215 may vary or remain constant across the mask grating 203 as described above. In some embodiments, which may be combined with other embodiments, the pitch 215 is less than or equal to the exposure wavelength of the UV light 109 at all points across the mask grating 203. For instance, in some embodiments, which may be combined with other embodiments, the UV light 109 is about 425 nm or less and the pitch 215 is less than or equal to about 425 nm. For example, the pitch 215 is less than or equal to 365 nm when the UV light 109 has a wavelength of 365 nm. The UV light 109 is therefore scattered from a collimated state that the UV light 109 has from a UV light source. In some embodiments, which may be combined with other embodiments, the pitch 215 is equal to the wavelength of the UV light 109 and the UV light 109 is scattered from the collimated state. The mask 200 does not require a diffuser to scatter the UV light 109 since the mask 200 grating has sub-wavelength pitch 215 and the mask pattern will not be resolved due to a diffraction limit.

The critical dimension 211 of the mask grating 203 affects the transmission rate of the UV light 109 through the mask 200. The critical dimension 211 may be in a range of about 25 nm to about 25 nm less than the pitch 215. When the pitch 215 is constant, the critical dimension 211 modulates the transmission rate of UV light 109 through the mask 200. Lowering the critical dimension 211 increases the transmission rate of UV light 109, which in turn causes more of the resist layer 107 to be removed during the photolithography process. Conversely, increasing the critical dimension 211 decreases the transmission rate of UV light 109 which in turn causes less of the resist layer 107 to be removed during the photolithography process. In some embodiments, which may be combined with other embodiments, the critical dimension 211 may vary across the mask grating 203 to tune the remaining resist thickness on wafer 105 (FIG. 1).

FIG. 2B shows the mask 200 in a second orientation 200B. The second orientation 200B of the mask 200 shows the mask grating 203 disposed on the first surface 205 of the mask substrate 201; however, in the second orientation 200B, the first surface 205 of the mask substrate 201 opposes the second surface 207 and faces the wafer 105. Thus, in FIG. 2B, the mask grating 203 is spaced at a second distance 219 away from the resist layer 107 of the wafer 105. The second distance 219 may be in a range from greater than 0 μm to about 6 mm, such as about 20 μm to about 1 mm, or such as about 250 μm.

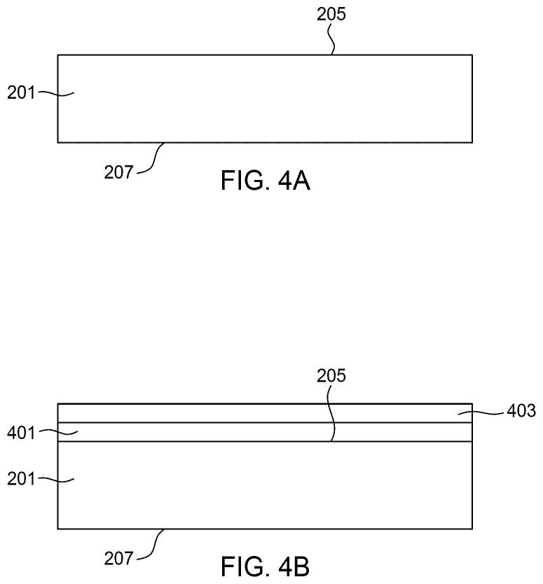

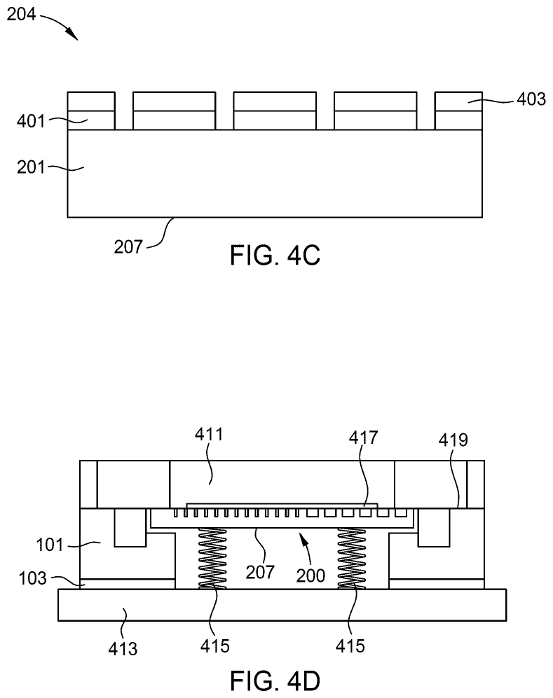

FIG. 3 is a flow diagram of a method 300 of forming the mask 200 according to some embodiments. In addition, FIGS. 4A-4D are schematic, cross-sectional views of the mask substrate 201 during the method 300 of forming the mask 200 according to some embodiments.

As shown in FIGS. 3, 4A, and 4B, at operation 301, an absorber layer 401 is deposited on the mask substrate 201. The absorber layer 401 is deposited on the first surface 205 of the mask substrate 201. In some embodiments, which may be combined with other embodiments, the absorber layer 401 is deposited by physical vapor deposition (PVD), chemical vapor deposition (CVD), atomic layer deposition (ALD) or spin on. In some embodiments, which may be combined with other embodiments, the absorber layer 401 includes at least one of chromium (Cr), silicon (Si), tungsten (W), tungsten carbide (WC),titanium nitride (TiN), nickel (Ni), gold (Au), molybdenum silicide (MoSi₂), tantalum (Ta), tantalum nitride (TaN), or ruthenium (Ru). The thickness of the absorber layer 401 may be dependent on the material used in the absorber layer 401. In some embodiments, which may be combined with other embodiments, the absorber layer 401 has a thickness in a range of about 60 nm to about 100 nm when Cr is used. In some embodiments, which may be combined with other embodiments, the absorber layer 401 forms the mask grating 203. In other embodiments, which may be combined with other embodiments, the mask grating 203 includes the absorber layer 401 and a protective layer 403. Thus, in some embodiments, which may be combined with other embodiments, the protective layer 403 may be deposited on the absorber layer 401. The protective layer 403 may be deposited by PVD, chemical vapor deposition (CVD), or atomic layer deposition (ALD). In some embodiments, which may be combined with other embodiments, the protective layer 403 includes at least one of silicon oxide (SiO, SiO₂), silicon nitride (SiN), titanium nitride (TiN), or a similar material. The protective layer 403 may have a thickness in a range of about 5 nm to about 50 nm.

As shown in FIGS. 3 and 4C, at operation 303, the plurality of grating structures 204 are formed in the absorber layer 401 and protective layer 403. The grating structures 204 may be etched in the absorber layer 401 and protective layer 403. The grating structures 204 may be patterned using litho-etch process. In some embodiments, which may be combined with other embodiments, each of the grating structures 204 have an absorber section and a protective section. The protective layer 403 may improve the process window leading to a higher yield. Space widths 213 may be formed by the etching. The etching exposes sections of the first surface 205 of the mask substrate 201. The grating structures may also have the critical dimensions 211. The critical dimension 211 may be in a range of about 25 nm to about 25 nm less than the pitch 215. The pitch 215 may vary across the mask grating 203 or may be constant. In addition, the pitch 215 may be less than or equal to the wavelength of the light to be used with the mask 200.

The mask grating 203 may be formed with a designed mask with a variable mask critical dimension based on the design target. The patterns can also be generated by image stitching. Image stitching uses multiple or a single pattern on the scanner/stepper mask and images the pattern at different locations on the absorber layer 401 to form a larger pattern in the absorber layer 401. Each location can use the same or different exposure conditions (such as dose and focus). Therefore, the pattern can be varying and larger than the design on the scanner/stepper mask. Image stitching is a useful tool to reduce the cost of scanner/stepper masks used to make the mask 200 when die size is large enough to require multiple scanner/stepper masks. Since the scanner/stepper masks are smaller than the mask substrate 201, image stitching increases the size of the pattern of the mask grating 203.

The pitch 215 and the critical dimension 211 may have better pattern dimension control than a mask written using the same mask writer tool due to imaging reduction by the scanner/stepper and a mature semiconductor process which transfers and defines the pattern of the grating structures 204 on the absorber layer 401. The reduction ratio can be different depending on what kind of lithography tool used.

A mask density transition boundary on the grating structures 204 may also generate a transition zone on the wafer 105 during the gray tone lithography due to diffraction. This transition zone means the thickness will not change from one design to another design immediately. Since the transition zone is caused by diffraction and interference, the larger the distance between the grating structures 204 and the surface of the resist layer 107, the larger the transition zone. This relationship with the transition zone is true for both diffuser-less masks and masks with a diffuser for gray tone lithography. However, sub-wavelength pitch in the mask 200 eliminates the need for the diffuser. The mask 200 can use collimated light directly as illumination and the proximity gap between mask 200 and wafer 105 may be small since the mask pattern will not be resolved due to the diffraction limit. Typically, the transition zone may be less than 30 μm when the proximity gap for exposure is set to a few hundred μm. This transition zone is far less than traditional masks with diffuser, which have typically have density transition zones of 50 μm or larger.

As shown in FIGS. 3 and 4D, at operation 305, the mask 200 is positioned in the mask assembly 100. The mask 200 is formed from a substrate 201. The mask 200 is put in the mask holder 101 to be used in a photolithography device. In some embodiments, which may be combined with other embodiments, standard masks are square shaped. As described above, in some embodiments, which may be combined with other embodiments, the mask 200 is formed on a wafer with a diameter of about 290 mm to about 310 mm, such as about 299.5 mm to about 300.5 mm. The mask 200 is therefore put in a mask assembly 100 to become the standard size. In some embodiments, which may be combined with other embodiments, the mask assembly 100 is square shaped and has a length and width of 14 inches. The mask 200 is properly aligned in the mask assembly 100. In one embodiment, which may be combined with other embodiments, a second surface 417 of the mask 200 is flush to a second surface 419 of the mask holder 101. In this configuration, the mask 200 can be used without any process change on the lithography tool. When the mask 200 is protruded or recessed from the mask holder 101, the gray tone lithography process may be performed, but may introduce risk for the lithography tool and the operation procedure or recipe may need to be adjusted. The mask 200 is aligned in the mask assembly 100 using aligning objects. The aligning objects include a cover glass 411 and a flat surface 413 with springs 415. FIG. 4D shows the cover glass 411 placed on top of the mask grating 203 and the springs 415 are positioned on the second surface 207 of the mask substrate 201. The springs 415 are connected to the flat surface 413. The flat surface 413 are also connected to the opaque layer 103. The aligning objects ensure the mask 200 is properly positioned in the mask assembly 100.

At operation 307, the mask assembly 100 is removed from the aligning objects. The mask assembly 100 may now be inserted into a photolithography chamber. FIG. 1 shows the mask assembly 100 ready to be used in a photolithography process.

As explained above and reiterated below, the present disclosure includes, without limitation, the following example implementations.

Clause 1: A mask, comprising: a substrate; and a gray-tone pattern grating disposed on the substrate, the gray-tone pattern grating defined by a plurality of structures disposed on the substrate, the structures comprising: an absorber layer disposed on the substrate, wherein the gray-tone pattern grating has a pitch that is less than or equal to an exposure wavelength of light to pass through the structures, the pitch defined as a distance between centers of adjacent structures of the plurality of structures.

Clause 2: The mask of any of the clauses, wherein the structures have a critical dimension defined as a width of the structures, the critical dimension in a range from about 25 nanometers (nm) to about 25 nm less than the pitch.

Clause 3: The mask of any of the clauses, wherein the structures have a thickness defined as a distance from a first surface of the substrate to a top surface of the structures, the thickness in a range from about 30 nm to about 150 nm.

Clause 4: The mask of any of the clauses, wherein the structures are oriented in a two-dimensional pattern that comprises a contact holes and pillar pattern.

Clause 5: The mask of any of the clauses, wherein the structures are oriented in a line and space pattern.

Clause 6: The mask of any of the clauses, wherein the substrate has a thickness in a range of about 750 micrometer (μm) to about 800 μm.

Clause 7: The mask of any of the clauses, wherein the structures further comprise a protective layer disposed on the absorber layer, the protective layer comprising silicon oxide, or silicon nitride.

Clause 8: The mask of any of the clauses, wherein the absorber layer comprises chromium, titanium nitride, nickel, gold, molybdenum silicide, tantalum, tantalum nitride, or ruthenium.

Clause 9: A mask assembly for gray-tone lithography, comprising: a mask, comprising: a substrate; and a gray-tone pattern grating with a plurality of grating structures comprising an absorber layer disposed on the substrate; a mask holder operable to secure the mask, the mask being inserted in the mask holder; a UV light source disposed above the mask operable to project UV light through the mask, wherein the gray-tone pattern grating has a pitch that is less than or equal to a wavelength of UV light projected by the UV light source, the pitch defined as a distance between centers of adjacent grating structures of the plurality of grating structures; and a substrate support positioned below the mask.

Clause 10: The mask assembly of any of the clauses, wherein the grating structures have a critical dimension defined as a width of the grating structures, wherein the critical dimension is in a range from about 25 nanometers (nm) to about 25 nm less than the pitch.

Clause 11: The mask assembly of any of the clauses, wherein the substrate has a thickness in a range of 750 micrometers (μm) to 800 μm.

Clause 12: The mask assembly of any of the clauses, wherein the mask has a diameter in a range of about 299.5 millimeters (mm) to about 300.5 mm.

Clause 13: The mask assembly of any of the clauses, wherein the gray-tone pattern grating of the mask is facing away from the substrate support and the mask is positioned in the mask holder.

Clause 14: The mask assembly of any of the clauses, wherein the gray-tone pattern grating of the mask is facing the substrate support and the mask is positioned in the mask holder.

Clause 15: A method of fabricating a mask, comprising: depositing an absorber layer on a first surface of a substrate; and forming a plurality of structures in the absorber layer by removing sections of the absorber layer, the structures forming a grating having a pitch that is less than or equal to an exposure wavelength of light to pass through the structures, the pitch defined as a distance between centers of adjacent grating structures of the plurality of structures.

Clause 16: The method of any of the clauses, further comprising: positioning the mask in a mask holder; and positioning the mask holder above a wafer for a photolithography process.

Clause 17: The method of any of the clauses, further comprising: passing light through the mask to perform a photolithography process on the wafer.

Clause 18: The method of any of the clauses, wherein a scanner/stepper mask imaged at different locations on the substrate forms the plurality of structures.

Clause 19: The method of any of the clauses, wherein the structures have a thickness in a range of about 30 nanometers (nm) to about 150 nm, and a critical dimension of in a range of about 25 nm to about 25 nm less than the pitch, wherein the critical dimension is defined as a width of the structures.

Clause 20: The method of any of the clauses, wherein a modulation of the thickness, the critical dimension, and the pitch of the structures in the grating is configured to affect a transmission rate of UV light through the mask.

In summation, the present disclosure generally relates to mask designs and fabrication for gray-tone lithography. More specifically, embodiments described herein relate to masks designed with a specific pitch to avoid needing diffusers. The mask is made by normal semiconductor process on a wafer such as film deposition, lithography or other similar processes. Benefits of the mask include a maximum mask size fit up to 300 mm in some embodiments. The mask has better pattern density control allowing a four times reduction in size by a scanner and lower transition zones for gray-tone process. The mask has a lower cost due to not requiring a high-end E-Beam writer in fabrication of the large format mask. The mask has design freedom by adjusting scanner recipe and is easy to clean and perform metrology. The wafer mask also allows for OPC to be performed.

While the foregoing is directed to embodiments of the present disclosure, other and further embodiments of the disclosure may be devised without departing from the basic scope thereof, and the scope thereof is determined by the claims that follow.

What is claimed is:

1. A mask, comprising:
a substrate; and
a gray-tone pattern grating disposed on the substrate, the gray-tone pattern grating defined by a plurality of structures disposed on the substrate, the structures comprising:
an absorber layer disposed on the substrate, wherein the gray-tone pattern grating has a pitch that is less than or equal to an exposure wavelength of light to pass through the structures, the pitch defined as a distance between centers of adjacent structures of the plurality of structures.

2. The mask of claim 1, wherein the structures have a critical dimension defined as a width of the structures, the critical dimension in a range from about 25 nanometers (nm) to about 25 nm less than the pitch.

3. The mask of claim 2, wherein the structures have a thickness defined as a distance from a first surface of the substrate to a top surface of the structures, the thickness in a range from about 30 nm to about 150 nm.

4. The mask of claim 3, wherein the structures are oriented in a two-dimensional pattern that comprises a contact holes and pillar pattern.

5. The mask of claim 3, wherein the structures are oriented in a line and space pattern.

6. The mask of claim 1, wherein the substrate has a thickness in a range of about 750 micrometer (μm) to about 800 μm.

7. The mask of claim 1, wherein the structures further comprise a protective layer disposed on the absorber layer, the protective layer comprising silicon oxide, or silicon nitride.

8. The mask of claim 1, wherein the absorber layer comprises chromium, titanium nitride, nickel, gold, molybdenum silicide, tantalum, tantalum nitride, or ruthenium.

9. A mask assembly for gray-tone lithography, comprising:
a mask, comprising:
a substrate; and
a gray-tone pattern grating with a plurality of grating structures comprising an absorber layer disposed on the substrate;
a mask holder operable to secure the mask, the mask being inserted in the mask holder;
a UV light source disposed above the mask operable to project UV light through the mask, wherein the gray-tone pattern grating has a pitch that is less than or equal to a wavelength of UV light projected by the UV light source, the pitch defined as a distance between centers of adjacent grating structures of the plurality of grating structures; and
a substrate support positioned below the mask.

10. The mask assembly of claim 9, wherein the grating structures have a critical dimension defined as a width of the grating structures, wherein the critical dimension is in a range from about 25 nanometers (nm) to about 25 nm less than the pitch.

11. The mask assembly of claim 9, wherein the substrate has a thickness in a range of 750 micrometers (μm) to 800 μm.

12. The mask assembly of claim 9, wherein the mask has a diameter in a range of about 299.5 millimeters (mm) to about 300.5 mm.

13. The mask assembly of claim 12, wherein the gray-tone pattern grating of the mask is facing away from the substrate support and the mask is positioned in the mask holder.

14. The mask assembly of claim 12, wherein the gray-tone pattern grating of the mask is facing the substrate support and the mask is positioned in the mask holder.

15. A method of fabricating a mask, comprising:
depositing an absorber layer on a first surface of a substrate; and
forming a plurality of structures in the absorber layer by removing sections of the absorber layer, the structures forming a grating having a pitch that is less than or equal to an exposure wavelength of light to pass through the structures, the pitch defined as a distance between centers of adjacent grating structures of the plurality of structures.

16. The method of claim 15, further comprising:
positioning the mask in a mask holder; and
positioning the mask holder above a wafer for a photolithography process.

17. The method of claim 16, further comprising:
passing light through the mask to perform a photolithography process on the wafer.

18. The method of claim 15, wherein a scanner/stepper mask imaged at different locations on the substrate forms the plurality of structures.

19. The method of claim 15, wherein the structures have a thickness in a range of about 30 nanometers (nm) to about 150 nm, and a critical dimension of in a range of about 25 nm to about 25 nm less than the pitch, wherein the critical dimension is defined as a width of the structures.

20. The method of claim 19, wherein a modulation of the thickness, the critical dimension, and the pitch of the structures in the grating is configured to affect a transmission rate of UV light through the mask.
